(19) United States
(12) Patent Application Publication
(10) Pub. No.: US 2026/0235967 A1
(43) Pub. Date: Aug. 13, 2026

(54) SUBSTRATE TRANSFER METHOD, SUBSTRATE PROCESSING APPARATUS, AND PROGRAM

(71) Applicant: Tokyo Electron Limited, Tokyo (JP)

(72) Inventors: Kenichirou MATSUYAMA, Kumamoto (JP); Sho KANO, Kumamoto (JP); Saori KOSAKI, Kumamoto (JP); Shingo KATSUKI, Kumamoto (JP)

(73) Assignee: Tokyo Electron Limited, Tokyo (JP)

(21) Appl. No.: 19/150,578

(22) PCT Filed: Jan. 15, 2024
(86) PCT No.: PCT/JP2024/000841

§ 371 Date: Jul. 24, 2025

(30) Foreign Application Priority Data
Jan. 27, 2023 (JP) 2023-010668

(51) Int. Cl. G03F 7/00; H10P 72/00; H10P 72/30

(52) U.S. Cl. CPC G03F 7/7075; G03F 7/70991; H10P 72/0474; H10P 72/3404

(57) ABSTRACT

A substrate transfer method using a substrate processing apparatus including a first rear-stage module, a second rear-stage module, a heating module, and a development module where a substrate is placed on each thereof at a rear stage of an exposure machine includes transferring a plurality of substrates belonging to a same lot before being unloaded from the exposure machine and received by a second rear-stage transfer mechanism to a storage module that stores the substrates in a region where an atmosphere different from a surrounding atmosphere is formed by a first rear-stage transfer mechanism and collectively storing the substrates therein, and receiving the substrates after being stored in the storage module by the second rear-stage transfer mechanism at an interval corresponding to a circulation movement time between modules of the second rear-stage transfer mechanism set for each lot, and sequentially transferring the substrates to the second rear-stage module.

### FIELD

The present disclosure relates to a substrate transfer method, a substrate processing apparatus, and a program.

### BACKGROUND

In manufacturing a semiconductor device, photolithography is performed on a semiconductor wafer (hereinafter, referred to as a wafer). Specifically, after a resist film is exposed along a predetermined pattern in an exposure machine, the wafer is transferred between modules in a substrate processing apparatus such that processing is performed in order of heating called post exposure bake (PEB) and development. Patent Literature 1 discloses that the wafer is transferred such that a time until the PEB is performed after exposure is constant.

### CITATION LIST

### Patent Literature

Patent Literature 1: JP 2008-130857 A

### SUMMARY

### Technical Problem

The present disclosure provides technology Capable of suppressing variations in a transfer state between substrates after exposure by an exposure machine and suppressing variations in a pattern formed on a substrate by development.

### Solution to Problem

A substrate transfer method according to the present disclosure is a substrate transfer method using a substrate processing apparatus including a transfer mechanism group that transfers a substrate extracted from a carrier to the carrier via a module group and an exposure machine,
the module group including a first rear-stage module, a second rear-stage module, a heating module, and a development module where the substrate is placed on each thereof at a rear stage of the exposure machine,
the transfer mechanism group including a front-stage transfer mechanism that transfers the substrate from the carrier to the exposure machine, a first rear-stage transfer mechanism that transfers the substrate from the exposure machine to the first rear-stage module, a second rear-stage transfer mechanism that transfers the substrate in order of the first rear-stage module, the heating module, the development module, and the second rear-stage module, and a third rear-stage transfer mechanism that transfers the substrate from the second rear-stage module to the carrier,
the substrate processing apparatus including a storage module that stores the substrates in a region where an atmosphere different from a surrounding thereof is formed,
the substrate transfer method comprising:
a storage step of transferring a plurality of the substrates belonging to a same lot before being unloaded from the exposure machine and received by the second rear-stage transfer mechanism to the storage module by the first rear-stage transfer mechanism and collectively storing them therein; and
a transfer step of receiving the substrates after being stored in the storage module by the second rear-stage transfer mechanism at an interval corresponding to a circulation movement time between modules of the second rear-stage transfer mechanism set for each of the lots, and sequentially transferring them to the second rear-stage module, the transfer step being performed following the storage step.

### Advantageous Effects of Invention

The present disclosure can suppress variations in a transfer state between substrates after exposure by an exposure machine, and can suppress variations in a pattern formed on a substrate by development.

### BRIEF DESCRIPTION OF DRAWINGS

FIG. 1 is a plan view of an application and development apparatus according to an embodiment of the present disclosure.

FIG. 2 is a longitudinal cross-sectional side view of the application and development apparatus.

FIG. 3 is a block diagram illustrating a transfer path in the application and development apparatus.

FIG. 4 is a block diagram illustrating the transfer path on a rear stage side of an exposure machine.

FIG. 5 is a block diagram illustrating an outline of transfer control.

FIG. 6 is a block diagram illustrating an outline of transfer control.

FIG. 7 is a block diagram illustrating an outline of transfer control.

FIG. 8 is a block diagram illustrating a transfer example.

FIG. 9 is a block diagram illustrating a transfer example.

FIG. 10 is a block diagram illustrating a transfer example.

FIG. 11 is a block diagram illustrating another transfer example.

### DESCRIPTION OF EMBODIMENTS

### Outline of Application and Development Apparatus

An outline of an application and development apparatus 1 which is an embodiment of a substrate processing apparatus of the present disclosure will be described. The application and development apparatus 1 applies a resist to a wafer W as a substrate to form a resist film, and transfers the wafer to an exposure machine D5. After the resist film is exposed along a predetermined pattern by the exposure machine D5, the application and development apparatus 1 supplies a developer to the wafer W and performs development processing to form a resist pattern.

A resist of one of a chemical amplification resist (CAR) and a metal oxide resist (MOR) is supplied to the wafer W to form the resist film. The wafer W supplied with the CAR is developed by a positive developer, and the wafer W supplied with the MOR is developed by a negative developer. As described above, one of a plurality of resists of different types is selected and supplied to the wafer W, and one of a plurality of developers of different types is selected and supplied according to the type of the selected resist. The wafer W where the MOR resist film is formed and the wafer W where the CAR resist film is formed are transferred along different paths in the application and development apparatus 1. Even if the resist film to be formed is either the CAR or the MOR, PEB is performed on the wafer W before development after exposure.

Incidentally, for each of the wafer W where the MOR resist film is formed and the wafer W where the CAR resist film is formed, when a time (Post Exposure Delay: PED time) until the PEB is performed after the exposure in a same lot varies, a line width (critical dimension: CD) of the resist pattern varies in a same lot. This is an influence of components in the air in a clean room where the application and development apparatus 1 is installed, and the longer a time exposed to the air, the more the resist film is deteriorated, and the CD deviates from a design value. In addition, a time from the end of the PEB to the start of the development is referred to as a Post PEB Delay (PPD). For the wafer W where the MOR resist film is formed, if the PPD time varies in a same lot, a relatively large variation in the CD may occur in the lot. As will be described later, if the PPD time is to be equalized between the wafers W in a same lot, it is conceivable that the PED time may vary between the wafers W.

In the application and development apparatus 1, a buffer module 42 capable of causing a plurality of wafers W to stand by under a nitrogen (N2) gas atmosphere is provided in a transfer path of the wafer W where the MOR resist film is formed. In addition, the wafer W is transferred so that the PPD time is equalized in a same lot, and regarding the deviation of the PED time, the buffer module 42 causes the wafer W to stand by to suppress the deterioration of the resist due to the atmosphere, thereby preventing the variation of the CD. Note that MOR is a resist containing a metal. The term “containing a metal” herein means including a metal as a constituent component, and does not mean including a metal as an impurity.

### Configuration of Application and Development Apparatus

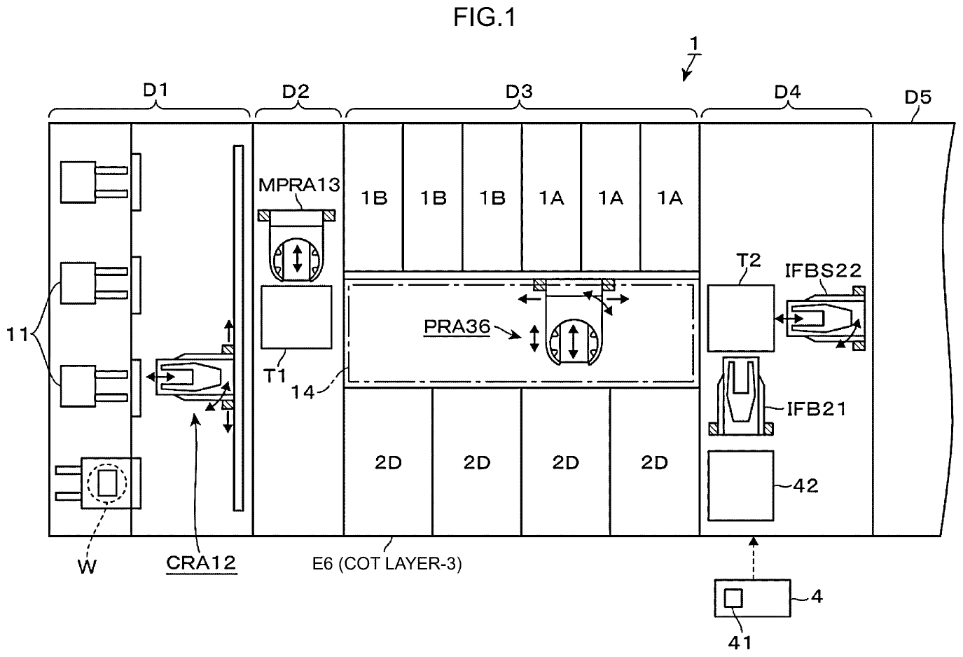

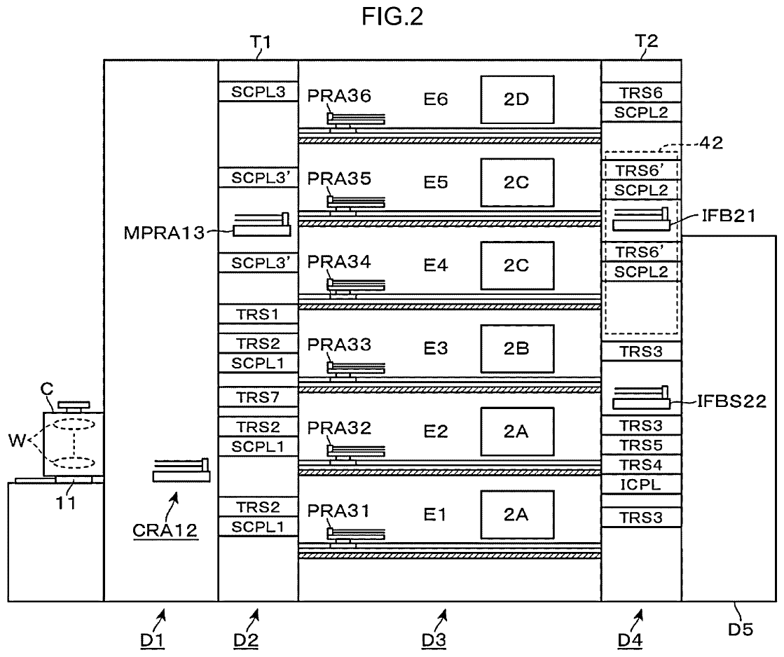

Hereinafter, the application and development apparatus 1 will be described with reference to a plan view of FIG. 1 and a longitudinal cross-sectional side view of FIG. 2. The application and development apparatus 1 is configured by connecting a carrier block D1, an intermediate block D2, a processing block D3, and an interface block D4 in a line in a left-right direction. The exposure machine D5 is connected to the right side of the interface block D4 (the side opposite to the side where the carrier block DI is located).

The carrier block D1 includes a plurality of stages 11, and a carrier C, which is a transfer container called a front opening unify pod (FOUP) capable of storing wafers W, can be placed on each of the stages 11. A maximum of 25 wafers W are stored in the carrier C. Further, the carrier block D1 includes a transfer mechanism 12, and delivers the wafer W to the carrier C on the stage 11.

The intermediate block D2 is provided with a tower T1 in which a large number of modules are laminated. Each module of the tower T1 can be accessed by a transfer mechanism 13 arranged on the rear side of the transfer mechanism 12 and the tower T1, and the transfer mechanism 12, and the transfer mechanisms 12 and 13 cooperate with each other to allow the delivery of the wafer W between the carrier C and each hierarchy of the processing block D3, which will be described later.

The processing block D3 is configured by laminating hierarchies E1 to E6 for performing liquid processing and heating processing on the wafer W in order from the bottom. The hierarchies E1 to E3 form a resist film, the hierarchies E1 and E2 applies the CAR, and the hierarchy E3 applies the MOR. The hierarchies E4 to E6 form a resist pattern by PEB and development. The hierarchies E4 and E5 forming a second region develop the CAR resist film, and the hierarchy E6 forming a first region develops the MOR resist film. In each hierarchy E (E1 to E6), the transfer and processing of the wafers Ware performed in parallel with each other.

The hierarchy E6 illustrated in FIG. 1 will be described as a representative of the hierarchies E1 to E6. A transfer path 14 of the wafer W extending in a left-right direction is formed at the center in a front-rear direction of the hierarchy E6. In front of the transfer path 14, a plurality of development modules 2D for MOR development are provided side by side in the left-right direction. Behind the transfer path 14, heating modules for heating the wafers W are laminated, and a large number of laminated bodies of the heating modules are provided side by side in the left-right direction. Examples of the heating module include a heating module that performs the PEB and a heating module that performs heating processing (post-baking) after development. Here, it is assumed that two types of heating modules 1A and IB are mounted, the heating module 1A performs the PEB, and the heating module 1B performs the post-baking. The heating modules 1A and 1B include a heating plate where the wafer W is placed and heated, and the temperature of the heating plate can be freely changed.

The transfer path 14 is provided with a transfer mechanism 36 that transfers the wafer W in the hierarchy E6. The transfer mechanism 36 includes a base that moves on the transfer path 14 and two substrate holding sections that move back and forth on the base. When one substrate holding section moves back and forth, the wafer W is received from the module, and then the other substrate holding section enters the module and sends the wafer W, so that the wafer W can be delivered so as to be replaced by the module. The replacement of the module may be referred to as replacement transfer. Note that the module is a place where the wafer W is placed other than the transfer mechanism, and a module that performs processing on the wafer W may be referred to as a processing module.

The hierarchies E4 and E5 have a configuration similar to that of the hierarchy E6 except that a development module 2C for CAR development is provided instead of the development module 2D for MOR development.

For the hierarchies E1 and E2, an application module 2A that supplies the CAR to the wafer W is provided instead of the development module 2D, and for the hierarchy E3, the application module 2A that supplies the MOR to the wafer W is provided instead of the development module 2D. In addition, the heating module in the hierarchies E1 to E3 heats the wafer W after the resist film is formed. Except for such a difference, the hierarchies E1 to E3 have a configuration similar to that of the hierarchy E6. Transfer mechanisms of the hierarchies E1 to E5 corresponding to the transfer mechanism 36 are denoted by 31 to 35, respectively.

Next, the interface block D4 will be described. The interface block D4 is provided with a tower T2 and transfer mechanisms 21 and 22. In the tower T2, a large number of modules are laminated similarly to the tower T1. The transfer mechanism 21 is used for transfer between modules of the tower T2, and is provided on the front side of the tower T2. The transfer mechanism 22 is used for transfer between the module of the tower T2 and the exposure machine D5, and is provided on the right side of the tower T2.

The towers T1 and T2 will be described. A delivery module TRS and a temperature adjustment module SCPL are provided in the towers T1 and T2, and these modules are used for loading/unloading with respect to the hierarchies E1 to E6 and delivery of the wafer W between blocks or between the block and the exposure machine D5. The SCPL is a module for adjusting the temperature of the wafer W, and includes a module for adjusting the temperature of the wafer W being transferred in the hierarchies and a module for adjusting the temperature of the wafer W immediately before being transferred to the exposure machine, in addition to the above-described applications of loading/unloading and delivery between the blocks. The SCPL for adjusting the temperature of the wafer W immediately before being transferred to the exposure machine D5 as described above is referred to as ICPL. A plurality of TRSs and a plurality of SCPLs for the above applications are provided. In addition, in the following description, as illustrated in FIG. 2, the TRSs and the SCPLs may be appropriately numbered to distinguish between the TRSs and the SCPLs having different arrangement places. Note that the number of wafers W that can be placed on the TRS and the SCPL is not limited to one, and two wafers W can be placed on TRS5 in the drawing.

### Buffer Module

The buffer module 42 which is a storage module is provided on the front side of the transfer mechanism 21. The buffer module 42 includes a case capable of loading/unloading the wafers W from the side, and can store the wafers W in the case side by side in an up-down direction. The number of wafers W that can be stored in the buffer module 42 is 36 or more, and the reason will be described later.

A supply port for supplying No gas is opened in the case, and the case has an Na gas atmosphere. Therefore, the atmosphere in a region in which the wafers W are stored in the case is different from the atmosphere outside the case. It is considered that the change in the property of the MOR after exposure that causes variations in the CD of the pattern described above is largely affected by moisture contained in the atmosphere. For this reason, as the gas to be supplied into the case, gas that makes the atmosphere different between the inside and the outside of the case, more specifically, gas that lowers the relative humidity in the case as compared with the outside of the case is preferably used. Therefore, the gas to be used is not limited to the N2 gas, and inert gas other than the N2 gas such as argon gas or gas such as dry air having a lower water content than the atmosphere around the case may be supplied into the case.

### Exposure Machine

When the wafer W can be loaded, the exposure machine D5 outputs a signal (in-ready signal) to that effect, and when the wafer W can be unloaded, the exposure machine D5 outputs a signal (out-ready signal) to that effect. A controller 4 to be described later receives these signals and controls the operation of the transfer mechanism 22, and the wafer W is delivered between the interface block D4 and the exposure machine D5. An interval from when one wafer W is loaded into the exposure machine D5 to when the exposure of the wafer W ends and the out-ready signal is output is defined as an exposure machine cycle time. When the wafer W is sequentially transferred to the exposure machine D5, the exposure machine cycle time is constant or substantially constant, and when the wafer W is transferred at a constant cycle, the out-ready signal is output at a constant or substantially constant cycle. In addition, a maximum of nine wafers W can be loaded into the exposure

### PJ

When the carrier C is loaded into the application and development apparatus 1, a process job (PJ) is set for the wafer W in the carrier C by the controller 4 described later. The PJ is information for designating a processing recipe (it also includes a transfer recipe indicating which type of module the wafer should be transferred to for processing, and which module among modules of a same type the wafer should be transferred to) ) in the wafer W and the wafer W to be transferred. Therefore, the transfer path of the wafer W in the application and development apparatus 1 is designated by the PJ. Since the wafers W of a same PJ are subjected to same processing, the wafers W of a same PJ are wafers W of a same lot.

Further, the processing recipe designated by the PJ includes information for calculating a required stay time (module using time (MUT) ) of the wafer W in each processing module. Specifically, the MUT is calculated based on the processing time of the wafer W. Even in a same processing module, the processing time varies depending on the designated processing recipe, and the MUT also varies.

When there are a plurality of wafers W of one PJ and a plurality of wafers W of other PJs, the operation of each transfer mechanism is controlled by the controller 4 to be described later such that the wafers W of one PJ are successively loaded into the apparatus and then the wafers W of other PJs are successively loaded into the apparatus. That is, after the wafers W of the preceding PJ are collectively loaded into the apparatus, the wafers W of the subsequent PJ are collectively loaded into the apparatus. In addition, each wafer W is transferred along a transfer path designated by each PJ, and is processed by each processing module in the transfer path according to a processing recipe designated by each PJ. Note that the wafers W of a same PJ are transferred to the subsequent modules in the order of loading into the apparatus. In addition, the wafers W are collectively and sequentially transferred to the exposure machine D5 for each PJ.

### Layer

In order to distinguish the transfer mechanisms in the apparatus described above from each other, individual names may be given. Specifically, the transfer mechanisms 12 and 13 may be referred to as CRA12 and MPRA13, respectively, the transfer mechanisms 31 to 36 may be referred to as PRA31 to PRA36, respectively, and the transfer mechanisms 21 and 22 may be referred to as IFB21 and IFBS22, respectively. In the transfer path, each section where transfer is performed by different transfer mechanisms is referred to as a “layer”. Among these layers, layers corresponding to the PRA31, the PRA32, and the PRA33 are referred to as a COT layer-1, a COT layer-2, and a COT layer-3, respectively, and layers corresponding to the PRA34, the PRA35, and the PRA36 are referred to as a DEV layer-1, a DEV layer-2, and a DEV layer-3, respectively.

For the COT layers (COT layer-1 to COT layer-3) and the DEV layers (DEV layer-1 to DEV layer-3), the PRA31 to the PRA36 repeatedly moves the modules in the layers in order, and replacement transfer of the wafer W is performed for each module except for the module at the entrance and the module at the exit of the layer. Therefore, the transfer mechanism circulates on the transfer path 14. By such an operation of the transfer mechanism, the wafers W are sequentially transferred one by one from the module on the upstream side to the module on the downstream side. At the time of switching the PJ, because a gap is formed in the transfer of the wafer W to the module is formed, there is a case where the transfer is not the replacement transfer.

### Description of Transfer Path

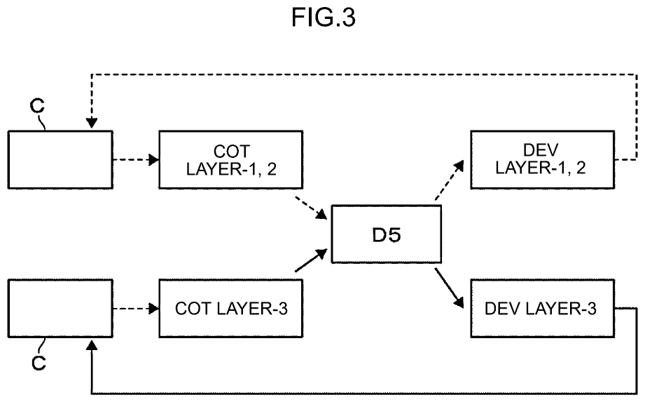

FIG. 3 schematically illustrates a transfer path in the application and development apparatus 1, and a solid arrow and a dotted arrow indicate a transfer path of the wafer W of the PJ (PJ in which the MOR resist film is formed and developed) of the MOR and a transfer path of the wafer W of the PJ (PJ in which the CAR resist film is formed and developed) of the CAR, respectively. The wafer W of the PJ of the MOR is returned from the carrier C to the carrier C via the COT layer-3, the exposure machine D5, and the DEV layer-3 in order. The wafer W of the PJ of the CAR is distributed from the carrier C to the COT layer-1 and the COT layer-2, transferred to the exposure machine D5 via these layers, distributed to the DEV layer-1 and the DEV layer-2, and returned to the carrier C via these layers.

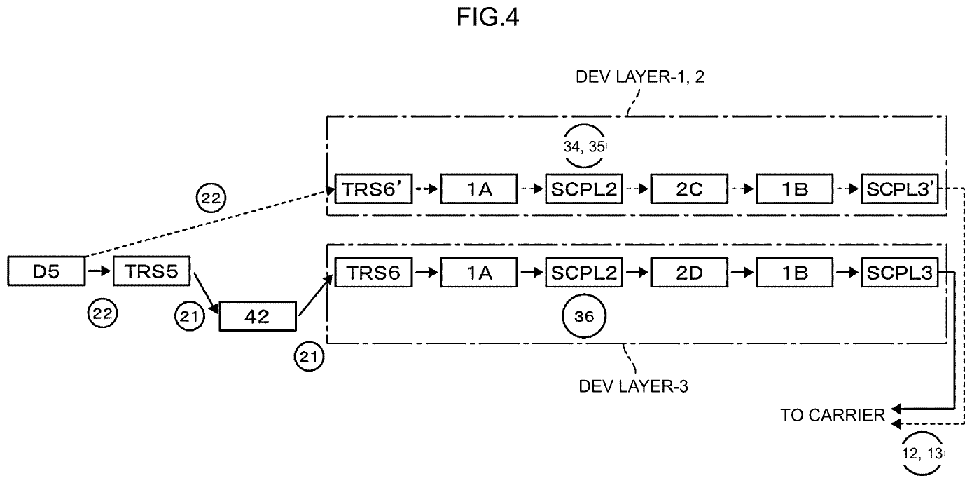

The transfer path of the wafer W will be described in detail with reference to FIG. 4 illustrating the transfer paths of the exposure machine D5 and the DEV layers in addition to FIG. 2 described above. Also in FIG. 4, the transfer path of the wafer W of the PJ of the MOR and the transfer path of the wafer W of the PJ of the CAR are respectively indicated by a solid arrow and a dotted arrow in a same manner as FIG. 3. In FIG. 4, a transfer mechanism used for transfer indicated by an arrow is illustrated in the vicinity of the arrow.

First, the transfer path of the wafer W of the PJ of the MOR will be described. The wafer W is discharged from the carrier C by the CRA12, transferred to the delivery module TRS1 of the tower T1, and transferred to the delivery module TRS2 at the height of the hierarchy E3 in the tower T1 by the MPRA13. In addition, the wafer W is received by the PRA33, and is transferred in the order of a temperature adjustment module SCPLI→an application module 2B→a heating module. The wafer W transferred as described above and on which the MOR resist film is formed is transferred to a delivery module TRS3 of the tower T2 and transferred in the order of IFB21→TRS4 of the tower T2→IFB21→ICPL→IFBS22→the exposure machine D5, and the resist film is exposed along a predetermined pattern.

The exposed wafer W is transferred in the order of IFBS22→TRS5 of the tower T2, transferred to the buffer module 42 by the IFB21, and transferred to TRS6 (which is the entrance of the DEV layer-3) at the height of the hierarchy E6 of the tower T2 by the IFB21. The wafer W is received by the PRA36 and transferred in the order of the heating module 1A→the SCPL2 of the tower T2→the development module 2D, and a resist pattern is formed on the wafer W. Thereafter, the wafer W is transferred in the order of the heating module 1B→SCPD3 of the tower T1 (which is the exit of the DEV layer-3), and is transferred in the order of the MPRA13→the delivery module TRS7 of the tower T1→the CRA12→the carrier C.

The transfer path of the wafer W of the PJ of the CAR is different from the transfer path of the wafer W of the PJ of the MOR in that the wafer W is transferred to the COT layer-1, 2 and the DEV layer-1, 2 and is transferred by the PRA31, the PRA32, the PRA34, and the PRA35; in the COT layer-1, 2, the wafer W is transferred to the application module 2A instead of the application module 2B; in the DEV layer-1, 2, the wafer W is transferred to the development module 2C instead of the development module 2D; the TRS and the CPL to which the wafer W is delivered are located at the heights of the COT layer-1, 2 and the DEV layer-1, 2 instead of being located at the heights of the COT layer-3 and the DEV layer-3 in the towers T1 and T2; and the wafer W is transferred from the exposure machine D5 to the module at the entrance of the DEV layer 1, 2 of the tower T2 without passing through the TRS5 and the buffer module 42 by the IFBS22. The module at the entrance and the module at the exit of the DEV layer-1, 2 are referred to as TRS6′ and SCPL3′, respectively.

The TRS6 and the TRS6′ correspond to first rear-stage modules, the SCPL3 and the SCPL3′ correspond to second rear-stage modules, and the TRS5 corresponds to a third rear-stage module. The CRA12, the MPRA13, and the PRA34 to the PRA36 constitute a front-stage transfer mechanism, the IFB21 and the IFBS22 correspond to a first rear-stage transfer mechanism, the PRA34 to the PRA36 correspond to a second rear-stage transfer mechanism, and the MPRA13 and the CRA12 constitute a third rear-stage transfer mechanism. Further, by providing the hierarchies E4 to E6, when the first rear-stage module, the second rear-stage module, the heating module for PEB, the development module, and the PRA that performs transfer between these modules are provided as sets thereof, three sets are provided.

### Controller

As illustrated in FIG. 1, the application and development apparatus 1 includes the controller 4 that is a computer. The controller 4 includes a program 41. In the program 41, a step group is incorporated such that transfer of the wafer W and processing of the wafer W in each module to be described later are performed, and a control signal is output to each module and each transfer mechanism of the wafer W. Each module and each transfer mechanism operate according to the control signal. The program 41 is stored in a storage medium such as a compact disk, a hard disk, or a DVD, and is installed in the controller 4. Furthermore, the program 41 is configured to be allowed to execute each transfer control by performing various calculations, comparisons, and determinations necessary for performing each transfer control to be described later.

### Outline of Transfer Control

Hereinafter, an outline of the transfer control performed by the controller 4 will be described. In the description, when modules in which the order in which the wafers W are transferred on the transfer path is same are defined as multi-modules, the number of modules to be used among the multi-modules is specified by the processing recipe designated by the PJ. Furthermore, as described above, the MUT (required stay time) of each processing module can be calculated from the information included in the processing recipe.

As described above, the PRA36 of the DEV layer-3 for MOR circulates on the transfer path 14 and accesses each processing module in order to perform replacement transfer in which the wafer W is replaced. In order to perform the replacement transfer, the number of used MUT/multi-modules is calculated for each of the heating module 1A, the SCPL2, the development module 2D, and the heating module 1B, which are processing modules other than the entrance and the exit of the DEV-layer 3, and a one circulation movement time (circulation movement time) of the PRA36 is determined from each calculated value.

Specifically, the larger one of a maximum value in the calculated values and the number of transfer processes from the entrance to the exit of the layer by the PRA36×predetermined time is defined as the circulation movement time, and the PRA36 circulates on the transfer path 14 in this circulation movement time. Since the wafer W is transferred in the order of the TRS6→the heating module 1A→the temperature adjustment module SCPL2→the development module 2D→the heating module 1B→the SCPL3, the number of transfer processes is counted as five. As such, the circulation movement time of the PRA36 of the DEV layer-3 corresponds to the PJ transferred to the DEV layer-3. Note that the circulation movement time of the PRA is similarly determined in the COT layer and DEV layer-1, 2, but detailed description is omitted.

As a rule of the transfer control, the transfer from the buffer module 42 to the DEV layer-3 is not performed for the PJ of the MOR until all the wafers W of the PJ reach the buffer module 42. Therefore, after all the wafers W belonging to a same lot are transferred to the buffer module 42, the wafers Ware sequentially transferred from the buffer module 42.

In addition, the wafer W of the PJ that has passed through the exposure machine D5 previously is defined as the wafer W of the preceding PJ, and the wafer W of the PJ that has passed through the exposure machine D5 after the wafer W is defined as the wafer W of the subsequent PJ. The wafer W of the preceding PJ is the wafer W belonging to the preceding lot, and the wafer W of the subsequent PJ is the wafer W belonging to the subsequent lot. As a further rule of the transfer control, while the wafer W of the preceding PJ is transferred through the DEV layer-3, the wafer W of the subsequent PJ is caused to stand by in the buffer module 42 and is not transferred to the DEV layer-3. Note that “while the wafer W of the preceding PJ is transferred through the DEV layer-3” means a period from when the first wafer W of the preceding PJ is transferred to the TRS6 as the entrance of the DEV layer-3 to when the last wafer W reaches the SCPL3 as the exit of the DEV layer-3, Therefore, after the wafer W most recently transferred to the TRS6 among the wafers W of the preceding PJ reaches the SCPL3, the transfer of the wafer W of the subsequent PJ from the buffer module 42 to the TRS6 is started.

Since the wafer W that has reached the SCPL3 is transferred by a transfer mechanism (MPRA13) different from the PRA36, this rule specifies that the transfer of the wafer W of the subsequent PJ using the PRA36 is not performed until the PRA36 is not related to the transfer of the wafer W of the preceding PJ. As described above, in the DEV layer-3, the transfer control is performed such that the wafer W is transferred by the PRA36 by 1 PJ at a time.

In the DEV layer-3, as described above, the PRA36 circulates with the circulation movement time corresponding to the PJ, and transfer is performed. On the other hand, the wafers W stored in the buffer module 42 are transferred one by one to the TRS6 which is the entrance of the DEV layer-3 by the IFB21 at a same time interval as the circulation movement time. Therefore, when the circulation movement time is A seconds, the wafer W is transferred to the TRS6 every A seconds, and the PRA36 receives the wafer W from the TRS6 every A seconds, and transfers the wafer W to the SCPL3 which is the exit of the DEV layer-3 (the entrance for the layer at the rear stage of the DEV layer-3).

When the wafer W is quickly transferred to the buffer module 42 after the out-ready signal is output from the exposure machine D5 by performing the transfer in this manner, a time from the unloading of the exposure machine D5 to the transfer to the development module 2D—a storage time in the buffer module 42 is equalized among the wafers W of a same PJ. That is, a time of exposure to the atmosphere from the unloading of the exposure machine D5 to the development is equalized between the wafers W. In addition, a time (=PPD time) from the end of the PEB to the transfer to the development module 2D is also equalized between the wafers W in a same PJ by the PRA36 moving at a constant circulation movement time and performing the transfer. Therefore, variations in the CD of the resist pattern to be formed are suppressed between the wafers W of a same PJ.

In order to describe the role of the buffer module 42 in detail, it is assumed that an apparatus configuration is employed in which the buffer module 42 is not provided and the wafer W processed by the exposure machine D5 is sequentially transferred to the entrance (TRS6) of the DEV layer-3. Then, in a case of a transfer situation where the DEV layer-3 is congested (many wafers W stay), it is considered that the wafers W cannot be transferred from the TRS5 between the exposure machine D5 and the DEV layer-3, and the TRS6 at the entrance of the DEV layer-3 to the subsequent modules, and some wafers W need to stay in these modules. As a result, some of the wafers W of a same PJ may be exposed to the atmosphere for a long time, and variations may occur in the CD of the resist pattern between the wafers W of the PJ.

In addition, a cycle time of the exposure machine D5 may actually vary, and for example, the out-ready signal may be output at a time earlier than a scheduled time, and the loading of the wafer W into the entrance of the DEV layer-3 may be accelerated. In this case, if the buffer module 42 is not provided, in order to make the PED time constant between the wafers W of a same PJ, it is necessary to shorten the circulation movement time for the PRA36, receive the wafer W from the entrance, and transfer the wafer W to the heating module 1A for PEB. However, changing the circulation movement time in that way means that the PPD time fluctuates. Therefore, providing the buffer module 42 and performing the transfer control prevents these problems. That is, by providing the buffer module 42, the transfer of the wafer W in the DEV layer-3 is performed without being affected by the operation of the exposure machine D5 and the stay of the wafer W in the DEV layer-3, and variations in the CD of the resist pattern between the wafers W of a same PJ can be prevented. For the PJ of the CAR, since an influence of the CD due to the fluctuation in the PPD time is small, the transfer control may be performed so that the circulation movement time is changed as described above.

### Specific Example of Transfer Control

Hereinafter, the transfer control will be described with specific examples. In the description, there is a case where the wafers W of each PJ are indicated with an alphabet in the order of being loaded into the exposure machine D5 (also in the order of being unloaded), and the individual wafers W in a same PJ are indicated with a number indicating the order of transfer designated by the PJ after the alphabet. Specifically, the PJ may be indicated as PJ-A, PJ-B . . . in the order of being loaded into the exposure machine D5. In addition, the wafers W of the PJ-A may be referred to as A1, A2, A3 . . . in the transfer order to the rear stage of the transfer path, and the wafers W of the PJ-B may be referred to as B1, B2, B3 . . . in the transfer order to the rear stage of the transfer path. In addition, in the comparison between the PJs, the PJ transferred from the exposure machine D5 previously may be referred to as the preceding PJ, and the wafer W of the preceding PJ is the wafer W belonging to the preceding lot.

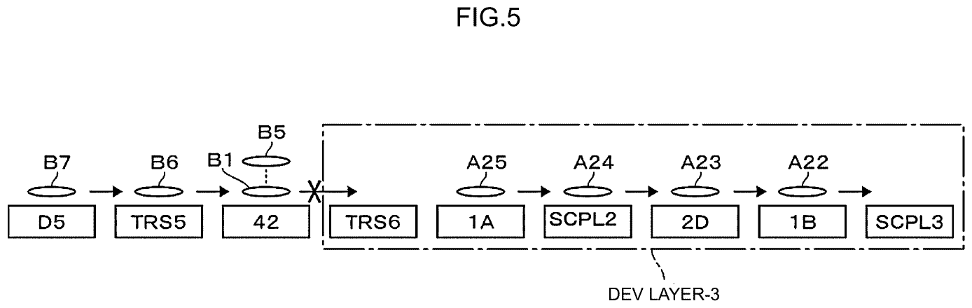

FIGS. 5, 6, and 7 illustrate a state in which the time gradually elapses and the stay situation of the wafer W of each PJ in the rear stage of the exposure machine D5 changes. In the examples illustrated in FIGS. 5 to 7, it is assumed that the number of wafers W of each of PJ-A to PJ-C is 25. Therefore, the wafers W of the PJ-A, the wafers W of the PJ-B, and the wafers W of the PJ-C may be represented as A1 to A25, B1 to B25, and C1 to C25, respectively.

FIG. 5 illustrates a state in which the wafers w of the PJ-A are being transferred through the DEV layer-3, the wafers W of the PJ-B are sequentially unloaded from the exposure machine D5, and several wafers among them are stored in the buffer module 42. As described above, the wafer W is transferred by 1 PJ at a time in the DEV layer-3. Therefore, the wafer W of the PJ-B is not transferred from the buffer module 42 to the DEV layer-3, and stands by in the buffer module 42.

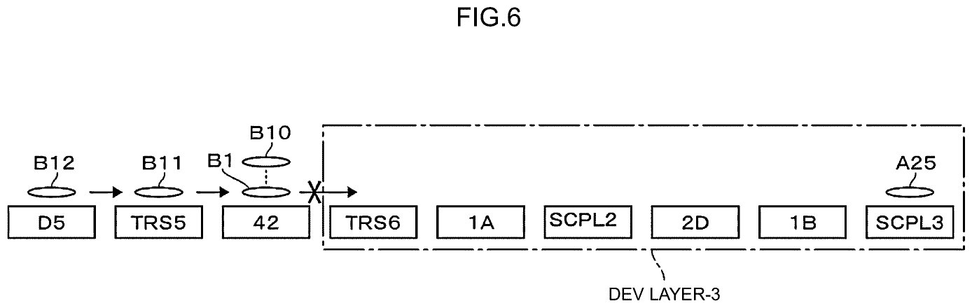

FIG. 6 illustrates a state in which, among the wafers W of the PJ-A, the wafer A25 transferred to the entrance of the DEV layer-3 last is transferred to the SCPL3 that is the exit of the DEV layer-3, the transfer of the wafer W of the PJ-A in the DEV layer-3 is completed, and the transfer of the wafer W of the PJ-B to the buffer module 42 is continued. As described above, until all the wafers W of one PJ reach the buffer module 42, the wafers W of the PJ are not unloaded from the buffer module 42. Therefore, in the state illustrated in FIG. 6, the transfer of each wafer W of the PJ-B in the buffer module 42 to the DEV layer-3 is not performed, and the standby of each wafer W in the buffer module 42 is continued.

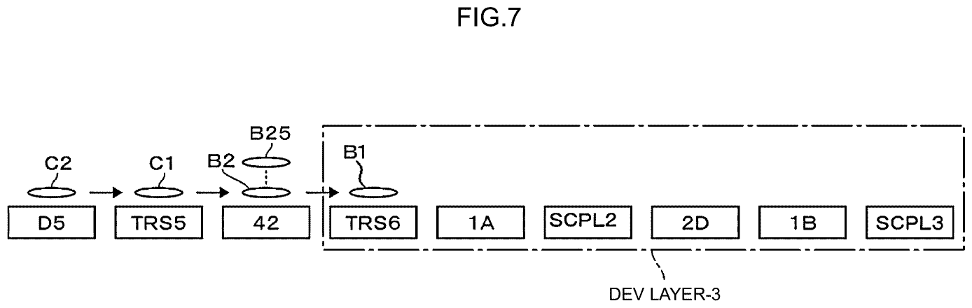

FIG. 7 illustrates a state after all the wafers W of the PJ-B reach the buffer module 42. Since all the wafers W reach the buffer module and the transfer of the wafer W of the PJ-A to the DEV layer-3 is completed, the transfer of the wafer W of the PJ-B to the DEV layer-3 is started in FIG. 7.

Incidentally, in FIG. 7, the wafer W of the PJ-C is unloaded from the exposure machine D5. When the time elapses from the state illustrated in FIG. 7, the wafer W of the PJ-B is sequentially unloaded in the buffer module 42 to generate a space therein, but the wafer W of the PJ-C is sequentially transferred to the space. That is, before the unloading of the wafer W of the preceding PJ is completed, the wafer W of the subsequent PJ is loaded, and both the wafers W of the PJ-B and the PJ-C are stored in the buffer module 42. As described above, the buffer module 42 can store the wafers W of the plurality of PJs. When the time further elapses, the transfer of the wafers W (wafers Bl to B25) of the PJ-B to the DEV layer-3 is completed, and all the wafers W (wafers C1 to C25) of the PJ-C are stored in the buffer module 42, the wafers W of the PJ-C are sequentially transferred to the DEV layer-3 similarly to the wafers W of the PJ-B.

### Change of Processing Condition in Processing Module

As described with reference to FIGS. 5 to 7, when the processing condition of the processing module is switched between PJs in transferring the wafer W, the time for which the wafer W stays in the buffer module 42 is used. It is specifically described that the temperature of PEB is different between the PJ-A and the PJ-B, and same four modules are used as the heating modules 1A for PEB in both the PJ-A and the PJ-B. For convenience, the four heating modules 1A are referred to as 1A-1 to 1A-4.

For each of the heating modules 1A-1 to 1A-4, when the last loaded wafer W among the wafers W of the PJ-A is unloaded from the module, the temperature of the heating plate is changed. Specifically, assuming that the wafers W of the PJ-A finally loaded into the heating modules 1A-1, 1A-2, 1A-3, and 1A-4 are A22, A23, A24, and A25, respectively, the temperature of the heating plate is changed in 1A-1, 1A-2, 1A-3, and 1A-4 as soon as these A22, A23, A24, and A25 are unloaded. Since the wafers A23 to A25 are located in the DEV layer-3 at the time of the start of the temperature change, the transfer of the wafer W of the PJ-B from the buffer module 42 to the DEV layer-3 is not performed. That is, the temperature of each heating plate is changed while the wafer W of the PJ-B stays in the buffer module 42.

Note that the temperature change of the heating plate of each heating module 1A is completed until the wafer W of the PJ-B is transferred. Therefore, if the wafer W of the PJ-B is unloaded from the buffer module 42 as soon as the above-described conditions are satisfied, in a case where the wafer W is transferred to the heating module 1A during the temperature change of the heating plate of the heating module 1A, timing of unloading the wafer W from the buffer module 42 is delayed. When the temperature change of the heating plate is completed, the wafer W of the PJ-B is transferred to the heating module 1A. Although the temperature change of the heating plate of the heating module 1A has been described as a representative example of the change of the processing condition of the module of the DEV layer-3, the processing condition can be similarly changed in other modules of the DEV layer-3 while the wafer W of the PJ-B stays in the buffer module 42.

### Number of Wafers W Stored in Buffer Module

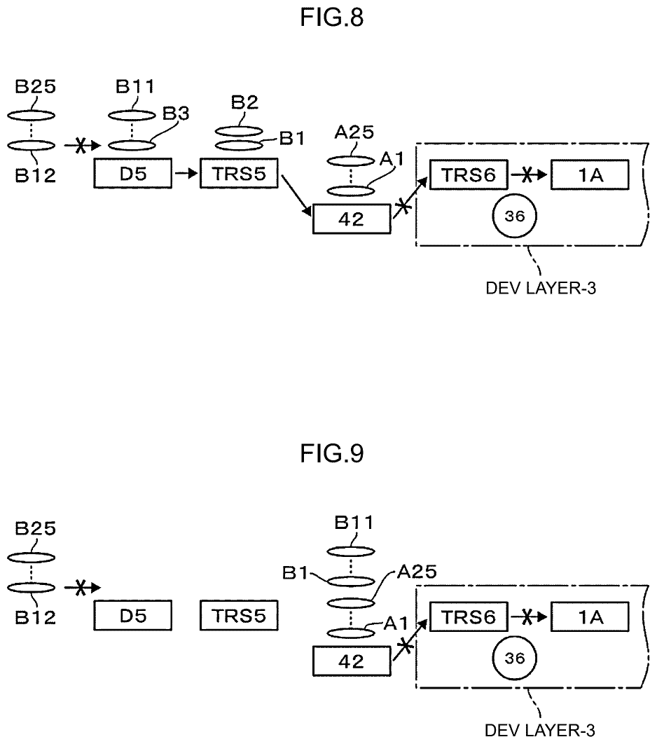

Incidentally, in the DEV layer-3, it is assumed that the transfer of the wafer W is temporarily disabled due to the fact that all of the multi-modules are disabled (FIG. 8). In that case, the transfer of the wafer W of the PJ of the MOR to the exposure machine DS and the transfer of the wafer W from the buffer module 42 to the DEV layer-3 are stopped. In addition, the wafer W already loaded into the exposure machine D5 and the wafer W in the TRS5 interposed between the exposure machine D5 and the buffer module 42 are sequentially transferred to the buffer module 42 and stand by in the buffer module 42 (FIG. 9). Thereafter, when the transfer in the DEV layer-3 becomes possible, the transfer of the wafer W of the PJ of the MOR to the exposure machine D5 and the transfer of the wafer W from the buffer module 42 to the DEV layer-3 are resumed.

The transfer control in FIGS. 8 and 9 will be described more specifically. If the PJ is changed for each carrier C (that is, if a same PJ is not set across the plurality of carriers C), 25 wafers W are stored in one carrier C as described above, and thus the maximum number of wafers W in one PJ is 25. As described with reference to FIGS. 5 to 7, for one PJ, the wafer W of the PJ is not unloaded from the buffer module 42 until all the wafers W are completely stored in the buffer module 42. Therefore, when the transfer in the DEV layer-3 becomes impossible, 25 wafers W of a same PJ may be stored in the buffer module 42. In FIGS. 8, 25 wafers W (A1 to A25) of the PJ-A are illustrated as being stored in the buffer module 42 as described above.

The exposure machine D5 can store a maximum of nine wafers W as described above. In addition, the TRS5 is configured to be allowed to store a maximum of two wafers W. Therefore, when the DEV layer-3 is in a state of being unable to be transferred, a total of 11 wafers W can be located at the exposure machine D5 and the TRS5, FIG. 7 illustrates a state in which the wafers B1 to B11 of the PJ-B are located at the exposure machine D5 and the TRS5 as described above. As described above, the transfer in the DEV layer-3 becomes impossible, so that the wafers B1 to B11 are stored together with the wafers A1 to A25 and caused to stand by, thereby preventing each of the wafers from being exposed to the atmosphere (FIG. 8). Therefore, the buffer module 42 is configured to be allowed to store a total of 36 or more wafers W.

Note that the number of the wafers W of the PJ-B is also 25, and FIGS. 7 and 8 illustrate that the wafers B12 to B25 stand by without being loaded into the exposure machine D5. When the transfer in the DEV layer-3 is enabled again, these wafers B12 to B25 are sequentially transferred to the exposure machine D5 and the buffer module 42, similarly to the wafers B1 to B12 previously transferred to the exposure machine D5 and the buffer module 42.

It is assumed that the number of the wafers W that can be stored in the buffer module 42 is smaller than 36, and is, for example, 25, which is the maximum number of one PJ. That is, a case where the wafers W of the exposure machine D5 and the TRS5 cannot be caused to stand by in the buffer module 42 when the transfer in the DEV layer-3 becomes impossible will be considered.

In this case, in order to prevent variations in the time of exposure to the atmosphere after exposure between the wafers W of the PJ-B due to the transfer impossibility in the DEV layer-3, the wafers W of the PJ-B cannot be loaded into the exposure machine D5 until the unloading of the wafers W of the PJ-A from the buffer module 42 is completed. For this reason, since the time from the loading of the wafer A25 of the PJ-A into the exposure machine D5 to the loading of the wafer B1 of the PJ-B into the exposure machine D5 becomes long, the operation efficiency of the exposure machine D5 may decrease, thereby decreasing the throughput of the application and development apparatus 1. Therefore, setting the number of wafers to be stored in the buffer module 42 as described above contributes to equalizing the line width of the pattern between same PJs while increasing the operation efficiency of the exposure machine D5 to improve the throughput of the application and development apparatus 1.

As described above, the buffer module 42 is configured to be allowed to store the wafer W of the module from the exposure machine D5 to immediately before the buffer module 42 in the transfer path when the transfer is impossible in the DEV layer-3. Therefore, in a case where another TRS is interposed in addition to the TRS5 in the transfer path between the exposure machine D5 and the buffer module 42, or in a case where the number of the wafers W that can be placed in the TRS5 is larger than two, the buffer module 42 may be configured such that the number of storable wafers increases accordingly.

### Using Conditions of Buffer Module

Incidentally, it has been described that all the wafers W of the PJ of the MOR are transferred to the buffer module 42. However, for example, in a case of a cycle time of the exposure machine>a cycle time of the DEV layer-3, the wafers W are transferred to the buffer module 42. That is, in a case of the cycle time of the exposure machine≤the cycle time of the DEV layer-3, the IFB21 that has received the wafer W from the TRS5 after transferring the wafer W in the order of the exposure machine D5→the TRS5 directly transfers the wafer W to the DEV layer-3 without transferring the wafer W to the buffer module 42. Note that the cycle time of the DEV layer-3 is a time required to transfer one wafer W to the subsequent layer of the DEV layer-3, and corresponds to the circulation movement time of the PRA36 described above in this example.

In a case of the cycle time of the exposure machine>the cycle time of the DEV layer-3, the transfer of the wafer W from the buffer module 42 to the DEV layer-3 and the transfer of the wafer W in the DEV layer-3 are performed at relatively short time intervals. Therefore, when the wafer W is transferred from the exposure machine D5 to the exit of the DEV layer-3 via the buffer module 42, the necessary transfer time is relatively short. That is, an influence of the transfer of the wafer via the buffer module 42 is small in securing a sufficient throughput of the apparatus.

However, in a case of the cycle time of the exposure machine≤the cycle time of the DEV layer-3, when the wafer W is transferred via the buffer module 42, the transfer of the wafer W from the buffer module 42 to the DEV layer-3 and the transfer of the wafer W in the DEV layer-3 are performed at relatively long time intervals. For this reason, the transfer time required for transferring the wafer W from the exposure machine D5 to the exit of the DEV layer-3 via the buffer module 42 becomes long, and it may be difficult to keep the throughput of the apparatus within a target range. Therefore, it is preferable to perform transfer to the buffer module 42 described in FIGS. 5 to 7 only in a case of the cycle time of the exposure machine >the cycle time of the DEV layer-3. However, when the cycle time of the exposure machine≤the cycle time of the DEV layer-3 is determined, the transfer to the buffer module 42 is not prohibited.

The exposure machine cycle time will be supplemented. If data communication regarding the exposure machine cycle time is possible between the controller 4 and the exposure machine D5, the controller 4 may use data transmitted from the exposure machine D5 as the exposure machine cycle time. In a case where such data communication cannot be performed, for example, a preset value may be used as the exposure machine cycle time, or the unloading interval of the wafer W from the exposure machine D5 may be regarded as the exposure machine cycle time to determine whether or not the cycle time of the exposure machine>the cycle time of the DEV layer-3 is satisfied.

Incidentally, it is assumed that a plurality of DEV layers-3 that process the MOR, such as the DEV layer (DEV layer-1, 2) that processes the PJ of the CAR, are provided in the apparatus, and the wafers W of a same PJ are distributed to each of the plurality of layers to perform processing. In that case, since the wafer W can be quickly transferred to the subsequent layer by the number of layers, it is only required to determine whether or not the cycle time of the exposure machine>the cycle time of the DEV layer-3 is satisfied with [the circulation movement time of the PRA36/the number of layers] as the cycle time of the DEV layer-3. The number of layers is the number of sets when the heating modules 1A and 1B, the development module 2D, the TRS6, the SCPL2 and 3, and the PRA36 are provided as sets thereof.

### Relationship between Transfer of Wafer W of PJ of MOR and Transfer of Wafer W of PJ of CAR

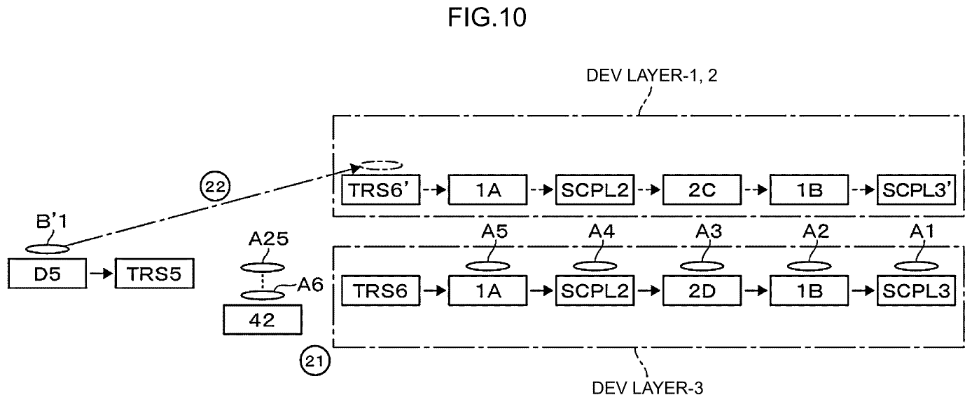

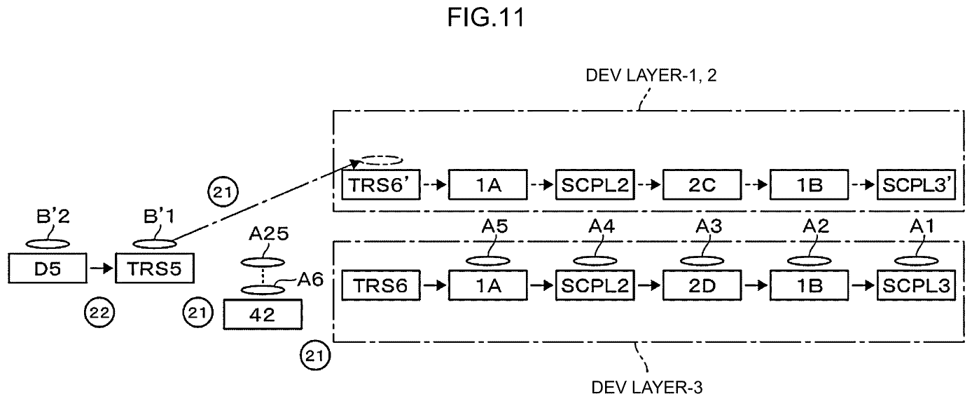

In a case where the wafer W of the PJ of the MOR is transferred to the exposure machine D5 and then the wafer W of the PJ of the CAR is transferred, even if the wafer W of the PJ of the MOR is stored in the buffer module 42, the wafer W of the PJ of the CAR can be transferred to the DEV layer-1 or the DEV layer-2. Specifically, the description is given with reference to FIG. 10. FIG. 10 illustrates an example in which the wafer W of the PJ-A of the MOR and the wafer W of the PJ-B of the CAR pass through the exposure machine D5 in this order. In order to indicate the PJ of the CAR, “ ′ ” is added after B. Even in the following description, the PJ of the CAR is distinguished from the PJ of the MOR by adding ′ after the alphabet representing the order of the PJ. In FIG. 10 and FIG. 11 described later, a transfer mechanism used for transfer between some modules is illustrated in the vicinity of the modules.

More specifically, the state illustrated in FIG. 10 indicates a state in which the transfer of the wafer W of the PJ-A from the buffer module 42 to a DEV layer-3A is started, A1 to A5 are already loaded into the DEV layer-3, and A6 and the subsequent wafers W stay in the buffer module 42. On the other hand, the wafer W of PJ-B′ is sequentially transferred to the exposure machine D5, and a wafer B′1 is being transferred to TRS6′ which is an entrance of the DEV layer-1 or 2. Therefore, in FIG. 10, before all the wafers W belonging to the preceding lot are transferred from the buffer module 42 to the TRS6, the wafers W belonging to the subsequent lot are transferred to the TRS6′. That is, overtaking is performed in which the wafers W belonging to the subsequent lot are located on the rear stage side of the transfer path as viewed from the exposure machine D5. Note that the MPRA13 accesses each of the SCPL3 which is the exit of the DEV layer-1, 2 and the SCPL3′ which is the exit of the DEV layer-3 to unload the wafer W, but as soon as the wafer W is transferred to the SCPL3 and the SCPL3′, the wafer W is received and transferred to the rear stage of the transfer path.

As described above, the development module 2D for MOR and the development module 2C for CAR are separately arranged into the DEV layer-3 and the DEV layer-1, 2, which are different layers, and transfer is performed between these layers so that the wafer W can be overtaken. As a result, the wafer W of the PJ-B′ of the CAR is transferred to the carrier C without waiting for completion of unloading of the wafer W of the PJ-A from the buffer module 42. Therefore, a decrease in the throughput of the application and development apparatus 1 is prevented.

Incidentally, in this example, the transfer of the wafer W of the PJ of the CAR from the exposure machine D5 to the DEV layer-1, 2 is performed by the IFBS22, and the transfer of the wafer W of the PJ of the MOR from the buffer module 42 to the DEV layer-3 is performed by the IFB21. Therefore, in overtaking the wafer W between the PJ-B′ and the PJJ-A, the wafer W of the PJ-B′ can be transferred to the DEV layer-1, 2 regardless of the transfer situation of the wafer W of the PJ-A. Therefore, a decrease in the throughput of the apparatus is more reliably prevented.

As described above, in the DEV layer-3 of the application and development apparatus 1, the wafer W of the PJ of the MOR is transferred by the PRA36 that moves with the circulation movement time corresponding to the PJ, and is transferred from the buffer module 42 to the DEV layer-3 at a same interval as the circulation movement time. As a result, the time for which the wafer W is exposed to the atmosphere after exposure and the time from when the wafer W is unloaded from the buffer module 42 to when the wafer W reaches each module of the DEV layer-3 are equalized between the wafers W of a same PJ. Therefore, it is possible to suppress variations in the CD of the resist pattern between the wafers W.

Incidentally, the arrangement of the transfer mechanisms and the modules of the interface block D4 is not limited to the example described above. For example, since the buffer module 42 only needs to be provided at a position accessible by the IFB21, it may be provided as a module constituting the tower T2. In addition, although it has been described that the loading of the wafer W into the exposure machine D5 is restricted in FIGS. 8 and 9, a module for causing the wafer W whose loading is restricted to stand by may be provided, and the wafer W stands by in the module until being loaded into the ICPL after processing in the COT layer, for example.

Since the IFB21 and the IFBS22 only need to be allowed to deliver the wafer W with respect to the modules and the exposure machine D5 described above, the arrangement can be appropriately changed. Further, the interface block D4 may be provided with a processing module that performs processing on the wafer W before exposure. The number of transfer mechanisms in the interface block D4 is not limited to only two of the IFB21 and the IFBS22, and an appropriate number may be provided according to the number and arrangement of installed modules.

In addition, the transfer path of the wafer W using the IFB21 and the IFBS22 is not limited to the above-described example. For example, the wafer W of the PJ of the CAR is transferred from the exposure machine D5 to the TRS5 by the IFBS22, and then transferred to the DEV layer-1, 2 by the IFB21. Specifically, FIG. 11 illustrates an example in which the wafers W of the PJ-A and the PJ-B′ are transferred in a same manner as FIG. 10, and the wafer W of the PJ-B′, which is the PJ of the CAR, is transferred to the DEV layer-1, 2 by the IFB21 via the TRS5 as described above.

Therefore, in the example illustrated in FIG. 11, the wafer W is loaded into the DEV layers-1 to 3 by a same transfer mechanism (IFB21). Even when the wafer is loaded into each layer of the DEV layers-1 to 3 by a same transfer mechanism as described above, it is possible to perform overtaking of the wafer W of the PJ-A of the wafer W of the PJ-B described in FIG. 10. The IFB21 sequentially transfers the wafer W of the PJ-A from the buffer module 42 to the DEV layer-3, and transfers the wafer W of the PJ-B′ transferred to the TRS5 during the transfer of the wafer of the PJ-A to the TRS6′ which is an entrance of the DEV layer-1, 2, so that the overtaking is performed.

If the transfer is performed as illustrated in FIG. 11, it is conceivable that the wafer W of the PJ-A is transferred from the buffer module 42 to the DEV layer-3 until the IFB21 receives the wafer W of the PJ-B′ from the TRS5 and transfers the wafer W to the DEV layer-1, 2. Therefore, it is conceivable that the transfer of the wafer W of the PJ-A to the DEV layer-3 is delayed by the transfer time from the TRS5 to the DEV layer-1, 2 at the maximum, but an influence of the pattern on the CD is suppressed to be low since the delay time is equal to or less than the transfer time of one module.

In order to prevent such a delay in transfer to the DEV layer-3, a work operator may select whether or not to perform overtaking from the controller 4. In a case where selection is made not to perform overtaking, the wafer W of the PJ-B′ of the CAR may be prevented from being loaded into the exposure machine D5 until all the wafers W of the PJ-A are unloaded from the buffer module 42. However, the loading into the exposure machine D5 is restricted as described above, so that the operation efficiency of the exposure machine D5 decreases, and it is preferable to perform overtaking.

Incidentally, for the wafer W of the PJ of the CAR, the influence of the CD due to the fluctuation of the PPD time is small as described above, but by suppressing the fluctuation of the PPD time between the wafers W of a same PJ, the uniformity for the CD can be further improved. Therefore, the wafer W of the PJ of the CAR may also be transferred according to a same rule as that of the wafer W of the PJ of the MOR described above. That is, the wafer W of the PJ of the CAR may be caused to stand by in the buffer module 42 and transferred, and the work operator may select whether or not to cause the wafer to stand by in the buffer module 42 from the controller 4. Therefore, when setting is executed in such a manner that no overtaking is performed between the wafer W of the PJ-A and the wafer W of the PJ-B′, the case where the wafer W of the PJ-B′ is not loaded into the exposure machine D5 has been described. However, the present disclosure is not limited to being not loaded as described above, and there is a case where the wafer passes through the exposure machine D5 and is stored in the buffer module 42.

However, the exposure machine cycle time of the PJ of the CAR tends to be shorter than that of the PJ of the MOR. Therefore, when the wafer W of the PJ of the CAR is caused to stand by in the buffer module 42, the wafer W of the PJ of the CAR is quickly transferred to the buffer module 42 due to such a short exposure machine cycle time, and thus, the buffer module 42 is likely to be in a full state. As described above, when the buffer module 42 is full, the wafer W of each subsequent PJ cannot be loaded into the exposure machine D5 in order to prevent variations in the time of the wafer exposed to the atmosphere after exposure, and thus there is a concern that the operation efficiency of the exposure machine D5 may decrease. Therefore, in the wafer W of the PJ of the CAR and the wafer W of the PJ of the MOR, only the wafer W of the PJJ of the MOR is preferably caused to stand by in the buffer module 42.

Incidentally, the PRA36 of the DEV layer-3 transfers the wafer W of a same PJ through the DEV layer-3 at a certain cycle, and the wafer W stands by in the N2 gas atmosphere until the reception of the PRA36, whereby the CD of the pattern between the wafers W can be equalized. Therefore, the buffer module 42 is not limited to the above arrangement, and the entrance of the DEV layer-3 may be configured by the buffer module 42. That is, the buffer module 42 may be provided on the transfer path from the exposure machine D5 to the entrance of the DEV layer-3, and the term “to the entrance” in this case includes the entrance itself.

However, if the entrance of the DEV layer-3 is the buffer module 42 as described above, it is necessary to provide the buffer module 42 in a range in which the PRA36 of the DEV layer-3 can receive the wafer W, so that the size of the buffer module 42, that is, the number of stored wafers W is limited. Therefore, it is preferable that the buffer module 42 is provided separately from the entrance of the DEV layer-3 as in the configuration described above, and the wafer W is transferred from the buffer module 42 to the entrance at intervals corresponding to the circulation movement time of the PRA36.

In addition, it has been described that after all the wafers W of one PJ are loaded into the buffer module 42, the transfer control is performed so as to start the unloading of the wafers W of one PJ from the buffer module 42. However, the unloading of the wafer of the PJ from the buffer module 42 may be started in a state where a part of the wafers W of one PJ has not reached the buffer module 42. Therefore, the buffer module 42 may collectively store all or some of the wafers W (wafers W belonging to one lot) of one PJ.

However, there is a concern that the unloading of the wafer W of one PJ from the buffer module 42 is delayed due to the influence of the loading of the wafer W of one PJ into the buffer module 42, or the loading of the wafer W into the buffer module 42 is delayed due to the influence of the unloading of the wafer W from the buffer module 42. Specifically, the loading and unloading with respect to the buffer module 42 are performed by the IFB21, but it is conceivable that a state in which one of the loading and the unloading is delayed occurs due to overlapping of the loading period and the unloading period. Even if the loading and the unloading are performed by different transfer mechanisms, there is a concern that one of the loading and the unloading is delayed in order to prevent interference between the operations of the transfer mechanisms. Such a delay in the loading or the unloading may affect the CD of the pattern between the wafers W. Therefore, as described with reference to FIGS. 5 to 7, after all the wafers W of one PJ are loaded into the buffer module 42, it is preferable to start unloading the wafers W of one PJ from the buffer module 42.

The interval of transferring the wafer W from the buffer module 42 to the DEV layer-3 may slightly deviate from the circulation movement time of the PRA36 of the DEV layer-3. That is, transferring the wafer W to the DEV layer-3 at an interval corresponding to the circulation movement time is not limited to that the circulation movement time and the interval are same. However, in order to equalize the line width of the pattern between the wafers W of a same PJ, the circulation movement time and the interval are preferably same.

Note that the substrate processing apparatus is not limited to the application and development apparatus. For example, an apparatus configured to perform only processing after exposure and development without performing resist application may be used. The substrate is not limited to the wafer W, and may be a flat panel display (FPD) substrate. The embodiments disclosed herein should be considered to be illustrative in all respects and not to be restrictive. The above embodiments may be omitted, replaced, modified, and combined in various forms without departing from the scope and spirit of the appended claims.

### Reference Signs List

C CARRIER
D5 EXPOSURE MACHINE
SCPL3 TEMPERATURE ADJUSTMENT MODULE
TRS6 DELIVERY MODULE
W WAFER
1 APPLICATION AND DEVELOPMENT APPARATUS
1A HEATING MODULE
12 TRANSFER MECHANISM (CRA)
13 TRANSFER MECHANISM (MPRA)
2D DEVELOPMENT MODULE
21 TRANSFER MECHANISM (IFB)
22 TRANSFER MECHANISM (IFBS)
36 TRANSFER MECHANISM (PRA)
42 BUFFER MODULE

1. A substrate transfer method using a substrate processing apparatus including a transfer mechanism group that transfers a substrate extracted from a carrier to the carrier via a module group and an exposure machine,
the module group including a first rear-stage module, a second rear-stage module, a heating module, and a development module where the substrate is placed on each thereof at a rear stage of the exposure machine,
the transfer mechanism group including a front-stage transfer mechanism that transfers the substrate from the carrier to the exposure machine, a first rear-stage transfer mechanism that transfers the substrate from the exposure machine to the first rear-stage module, a second rear-stage transfer mechanism that transfers the substrate in order of the first rear-stage module, the heating module, the development module, and the second rear-stage module, and a third rear-stage transfer mechanism that transfers the substrate from the second rear-stage module to the carrier,
the substrate processing apparatus including a storage module that stores the substrates in a region where an atmosphere different from a surrounding atmosphere is formed,
the substrate transfer method comprising:
a storage step of transferring a plurality of the substrates belonging to a same lot before being unloaded from the exposure machine and received by the second rear-stage transfer mechanism to the storage module by the first rear-stage transfer mechanism and collectively storing the substrates therein; and
a transfer step of receiving the substrates after being stored in the storage module by the second rear-stage transfer mechanism at an interval corresponding to a circulation movement time between modules of the second rear-stage transfer mechanism set for each of the lots, and sequentially transferring the substrates to the second rear-stage module, the transfer step being performed following the storage step.

2. The substrate transfer method according to claim 1, wherein
the storage step includes a step of causing the first rear-stage transfer mechanism to transfer the substrate from the exposure machine to the storage module, and
the transfer step includes a step of sequentially transferring the substrate of the storage module from the storage module to the first rear-stage module at an interval corresponding to the circulation movement time by the first rear-stage transfer mechanism.

3. The substrate transfer method according to claim 2, wherein
the transfer step includes a step of starting transfer of the substrates to the first rear-stage module after all the substrates belonging to a same lot are transferred to the storage module.

4. The substrate transfer method according to claim 2, wherein
when a lot of the substrates to be loaded into the exposure machine previously is defined as a preceding lot and a lot of the substrates to be loaded into the exposure machine after the preceding lot is defined as a subsequent lot, the storage step includes a step of loading the substrates of the subsequent lot into the storage module before completing unloading of the substrates of the preceding lot from the storage module.

5. The substrate transfer method according to claim 4, wherein
the transfer step includes a step of starting transfer of substrates of the subsequent lot from the storage module to the first rear-stage module after a substrate transferred to the first rear-stage module last among substrates of the preceding lot reaches the second rear-stage module.

6. The substrate transfer method according to claim 2, wherein
the storage step includes a step of storing all substrates belonging to a same lot in the storage module, and
the transfer step includes a step of starting transfer to the first rear-stage module after all the substrates belonging to the same lot are stored in the storage module.

7. The substrate transfer method according to claim 6, wherein
the module group includes a third rear-stage module where the substrate before being transferred from the exposure machine to the storage module is placed,
the number of substrates capable of being stored in the storage module is equal to or larger than a sum of the number of substrates capable of being stored in the carrier, the number of substrates capable of being stored in the exposure machine, and the number of substrates capable of being placed on the third rear-stage module, and
the substrate transfer method comprises a step of causing the first rear-stage transfer mechanism to transfer the substrates in the exposure machine and the first rear-stage module to the storage module and to cause the substrates to stand by, when transfer of the substrate by the second rear-stage transfer mechanism is disabled.

8. The substrate transfer method according to claim 2, wherein
a first region and a second region each including a set of the first rear-stage module, the second rear-stage module, the heating module, the development module, and the second rear-stage transfer mechanism are provided in the substrate transfer device, and
the storage step includes a step of transferring only a lot of the substrates to be transferred to the first rear-stage module in the second region among the first region and the second region to the storage module.

9. The substrate transfer method according to claim 8, wherein
when a lot of the substrates to be loaded into the exposure machine previously is defined as a preceding lot and a lot of the substrates to be loaded into the exposure machine after the preceding lot is defined as a subsequent lot, the transfer step includes a step of transferring the substrates belonging to the subsequent lot to the first rear-stage module in the second region before all of the substrates belonging to the preceding lot are transferred to the first rear-stage module in the first region.

10. The substrate transfer method according to claim 9, wherein
the development module in the first region develops a resist containing a metal, and
the development module in the second region develops a chemically amplified resist.

11. The substrate transfer method according to claim 1, wherein
an atmosphere different from a surrounding atmosphere in the storage module is an inert gas atmosphere.

12. The substrate transfer method according to claim 1, wherein
when an interval at which the substrate is allowed to be unloaded after the substrate is loaded into the exposure machine is defined as an exposure machine cycle time, and
when the first rear-stage module, the second rear-stage module, the heating module, and the development module where the substrate of the lot is transferred to each thereof and the second rear-stage transfer mechanism that transfers the lot is provided as sets thereof, the exposure machine cycle time is longer than the circulation movement time/number of the sets.

13. A substrate processing apparatus including a transfer mechanism group that transfers a substrate extracted from a carrier to the carrier via a module group and an exposure machine,
the module group including a first rear-stage module, a second rear-stage module, a heating module, and a development module where the substrate is placed at a rear stage of the exposure machine,
the transfer mechanism group including a front-stage transfer mechanism that transfers the substrate from the carrier to the exposure machine, a first rear-stage transfer mechanism that transfers the substrate from the exposure machine to the first rear-stage module, a second rear-stage transfer mechanism that transfers the substrate in order of the first rear-stage module, the heating module, the development module, and the second rear-stage module, and a third rear-stage transfer mechanism that transfers the substrate from the second rear-stage module to the carrier,
the substrate processing apparatus comprising:
a storage module that stores the substrates in a region where an atmosphere different from a surrounding atmosphere is formed; and
a controller that outputs a control signal to execute a storage step of transferring a plurality of the substrates belonging to a same lot before being unloaded from the exposure machine and received by the second rear-stage transfer mechanism to the storage module by the first rear-stage transfer mechanism and collectively storing the substrates therein, and a transfer step of receiving the substrates after being stored in the storage module by the second rear-stage transfer mechanism at an interval corresponding to a circulation movement time between modules of the second rear-stage transfer mechanism set for each of the lots, and sequentially transferring the substrates to the second rear-stage module, the transfer step being performed following the storage step.

14. A non-transitory computer-readable medium having stored therein a computer program used in a substrate processing apparatus, wherein
the computer program causes a computer to execute a group of steps to execute the substrate transfer method according to claim 1.
